(19) United States
(12) Patent Application Publication
(10) Pub. No.: US 2025/0248266 A1
(43) Pub. Date: Jul. 31, 2025

(54) DISPLAY DEVICE AND ELECTRONIC DEVICE INCLUDING THE SAME

(71) Applicant: SAMSUNG DISPLAY CO., LTD., YONGIN-SI (KR)

(72) Inventor: JUN NAMKUNG, Yongin-si (KR)

(21) Appl. No.: 19/038,756

(22) Filed: Jan. 28, 2025

(30) Foreign Application Priority Data
Jan. 31, 2024 (KR) 10-2024-0014507

(51) Int. Cl. H10K 59/65; H10K 59/126

(52) U.S. Cl. CPC H10K 59/65; H10K 59/126

(57) ABSTRACT

A display device includes: a display panel including a display area, in which a plurality of pixels are arranged, and a component area that is adjacent to the display area, wherein a first hole is provided in the display panel and overlaps the component area; and a metal plate disposed under the display panel, wherein a second hole is provided in the metal plate and overlaps the first hole, and wherein a first groove is provided in the metal plate and is spaced apart from the second hole.

### CROSS-REFERENCE TO RELATED APPLICATION

This application claims priority under 35 U.S.C. § 119 to Korean Patent Application No. 10-2024-0014507, filed on Jan. 31, 2024, in the Korean Intellectual Property Office (KIPO), the disclosure of which is incorporated by reference herein in its entirety.

### TECHNICAL FIELD

Embodiments of the present invention relate to a display device and an electronic device including the display device.

### DISCUSSION OF THE RELATED ART

A display device is a device that displays an image for providing information to a user in visual form. Recently, thickness and weight of the display device have become thinner and lighter, and range of use of the display device has become wider.

As a display area among the display devices becomes enlarged, various functions may be added to the display area. For example, an optical component such as a camera, a proximity sensor, etc. may be added to the enlarged display area. However, the optical component should be positioned to face an outside of the display device to recognize light. Accordingly, a hole (or a component area) may be formed in one portion of the display area, and the optical component may be disposed in the hole.

### SUMMARY

According to an embodiment of the present invention, a display device includes: a display panel including a display area, in which a plurality of pixels are arranged, and a component area that is adjacent to the display area, wherein a first hole is provided in the display panel and overlaps the component area; and a metal plate disposed under the display panel, wherein a second hole is provided in the metal plate and overlaps the first hole, and wherein a first groove is provided in the metal plate and is spaced apart from the second hole.

In an embodiment of the present invention, the metal plate includes a first surface, which faces the display panel, and a second surface opposite to the first surface, and the first groove is provided in the second surface.

In an embodiment of the present invention, the first groove is a portion in which a portion of the metal plate is removed from the second surface of the metal plate.

In an embodiment of the present invention, the first groove is disposed in a portion of the display area.

In an embodiment of the present invention, the first groove surrounds the second hole.

In an embodiment of the present invention, the first groove has an annular shape.

In an embodiment of the present invention, a second groove is provided in the metal plate and is spaced apart from the first groove.

In an embodiment of the present invention, the metal plate includes a first surface, which faces the display panel, and a second surface opposite to the first surface, and each of the first groove and the second groove is provided in the second surface.

In an embodiment of the present invention, each of the first groove and the second groove is a portion in which a portion of the metal plate is removed from the second surface of the metal plate.

In an embodiment of the present invention, a height of the first groove and a height of the second groove are a same as each other.

In an embodiment of the present invention, the second groove surrounds the first groove.

In an embodiment of the present invention, the first groove extends along a first circle, and the second groove extends along a second circle.

In an embodiment of the present invention, an edge of the metal plate has a chamfered shape in a cross-sectional view.

In an embodiment of the present invention, the metal plate includes a first surface, which faces the display panel, and a second surface opposite to the first surface, and the edge of the metal plate is spaced apart from the first surface, in the cross-sectional view.

In an embodiment of the present invention, the edge of the metal plate has a shape that approaches a center of the second hole as the edge approaches the display panel.

In an embodiment of the present invention, the metal plate includes a side surface connecting the first surface and the second surface to each other, wherein an angle between the chamfered edge of the metal plate and the side surface of the metal plate is an obtuse angle.

In an embodiment of the present invention, the display device further includes: conductive light-blocking member covering a side surface of the display panel that is exposed through the first hole.

In an embodiment of the present invention, the conductive light-blocking member covers a side surface of the metal plate that is exposed through the second hole.

In an embodiment of the present invention, the conductive light-blocking member fills at least a portion of the first groove.

In an embodiment of the present invention, the metal plate includes a second groove that is spaced apart from the first groove, and the conductive light-blocking member fills the first groove and at least a portion of the second groove.

According to an embodiment of the present invention, a display device includes: a display panel including a display area, in which a plurality of pixels are arranged, and an auxiliary area that is adjacent to the display area, wherein the display panel includes a first hole overlapping the auxiliary area; and a metal plate disposed on the display panel, wherein the metal plate includes a second hole and a first groove, wherein the second hole overlaps the first hole, and the first groove is spaced apart from the second hole.

In an embodiment of the present invention, the auxiliary area is disposed between adjacent pixels among the plurality of pixels.

In an embodiment of the present invention, the metal plate includes a first surface, which faces the display panel, and a second surface opposite to the first surface, and wherein the first groove is provided in the second surface.

In an embodiment of the present invention, the first groove is a portion in which a portion of the metal plate is removed from the second surface of the metal plate.

In an embodiment of the present invention, the first groove is disposed in a portion of the display area.

In an embodiment of the present invention, the first groove surrounds the second hole.

In an embodiment of the present invention, the first groove extends along a circle.

According to an embodiment of the present invention, an electronic device includes: a display panel including a display area, in which a plurality of pixels are arranged, and a component area that is adjacent to the display area, wherein a first hole is provided in the display panel and overlaps the component area; a metal plate disposed under the display panel, wherein a second hole is provided in the metal plate and overlaps the first hole, and wherein a first groove is provided in the metal plate and is spaced apart from the second hole; and a memory device configured to store data.

### BRIEF DESCRIPTION OF THE DRAWINGS

The above and other features of the present invention will become more apparent by describing in detail embodiments thereof, with reference to the accompanying drawings, in which:

FIG. 1 is a plan view illustrating a display device according to an embodiment of the present invention.

FIG. 2 is a plan view illustrating an example of an area A of FIG. 1.

FIG. 3 is a cross-sectional view of the display device of FIG. 2 taken along line I-I′.

FIG. 4 is an enlarged cross-sectional view of a metal plate included in the display device of FIG. 3.

FIG. 5 is a cross-sectional view illustrating a pixel included in the display device of FIG. 2.

FIG. 6 is a plan view illustrating an example of area A of FIG. 1.

FIG. 7 is a cross-sectional view illustrating an example of the display device of FIG. 6 taken along line II-II′.

FIG. 8 is an enlarged cross-sectional view of a metal plate included in the display device of FIG. 7.

FIG. 9 is a cross-sectional view illustrating an example of the display device of FIG. 6 taken along line II-II′.

FIG. 10 is an enlarged cross-sectional view of a metal plate included in the display device of FIG. 9.

FIG. 11 is a block diagram illustrating an electronic device according to embodiments.

FIG. 12 is a diagram illustrating an example in which the electronic device of FIG. 11 is implemented as a smart phone.

### DETAILED DESCRIPTION OF THE EMBODIMENTS

Hereinafter, display devices in accordance with embodiments of the present invention will be described in more detail with reference to the accompanying drawings. The same reference numerals are used for the same components in the drawings and specification, and redundant descriptions of the same components will be omitted or briefly discussed.

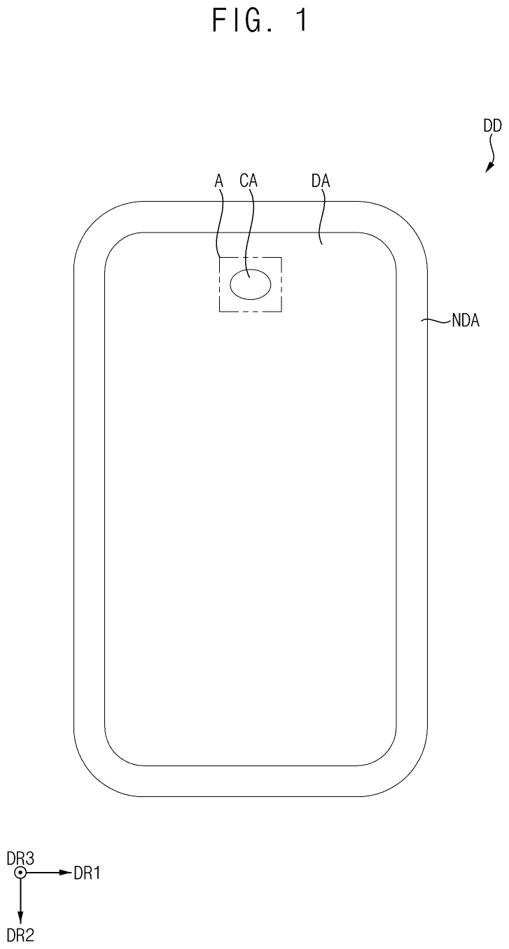

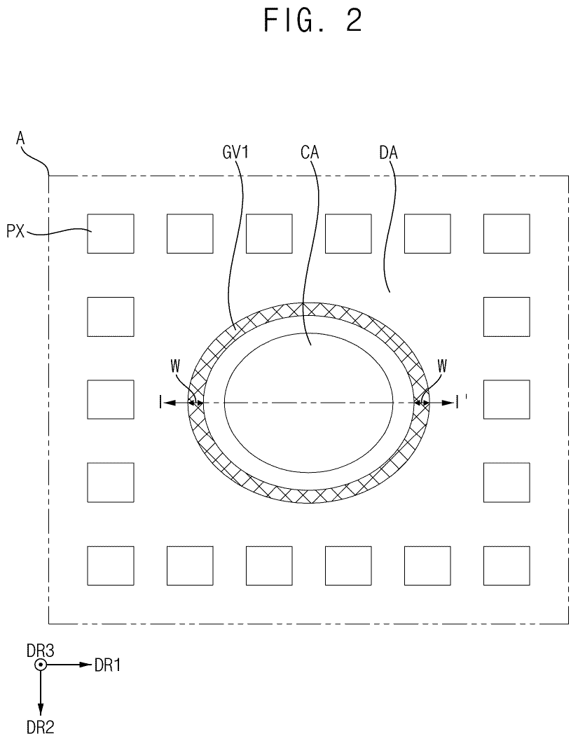

FIG. 1 is a plan view illustrating a display device according to an embodiment of the present invention. FIG. 2 is a plan view illustrating an example of an area A of FIG. 1.

Referring to FIGS. 1 and 2, a display device DD may include a display area DA, a non-display area NDA, and a component area CA. The display area DA may be an area in which an image is displayed by generating light or adjusting a transmittance of light that is provided from an external light source.

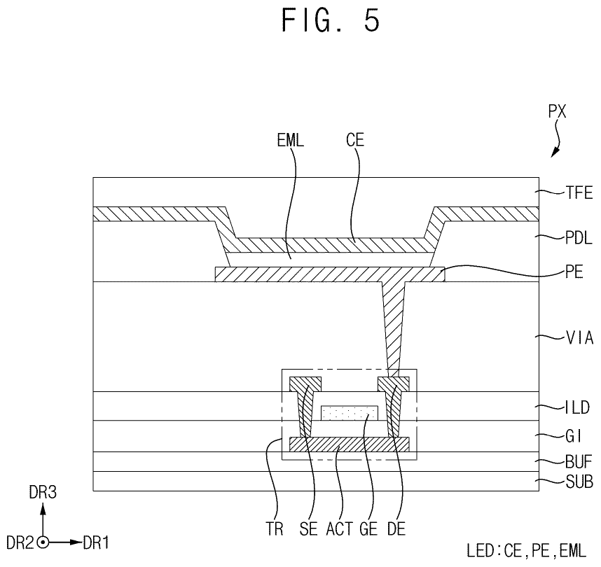

A plurality of pixels PX may be disposed in the display area DA. Each of the plurality of pixels PX may be an area in which light is emitted from a light emitting element (e.g., a light emitting element LED of FIG. 5) to an outside of the display device DD.

The plurality of pixels PX may be repeatedly arranged in a first direction DR1 and a second direction DR2 crossing the first direction DR1 in the plan view. In an embodiment of the present invention, the plurality of pixels PX might not be disposed in the component area CA. However, the present invention is not limited thereto, and in an embodiment of the present invention, some of the plurality of pixels PX may be disposed in the component area CA. In this case, light may be emitted not only from the display area DA but also from the component area CA.

Components for transmitting a signal to the display area DA may be disposed in the non-display area NDA. For example, a driver may be disposed in the non-display area NDA. The driver may provide a signal or voltage to the plurality of pixels PX. For example, the driver may include a data driver, a gate driver, and the like. The non-display area NDA might not display an image. The non-display area NDA may be disposed around the display area DA. For example, the non-display area NDA may surround at least a portion of the display area DA.

The component area CA may be in contact with the display area DA. For example, the component area CA may be disposed inside the display area DA. The component area CA may be disposed between adjacent pixels among the plurality of pixels PX. Optical components such as a camera, a proximity sensor, and the like may be disposed in the component area CA. For example, the component area CA may be referred to as an auxiliary area.

In an embodiment of the present invention, the component area CA may be disposed at an upper center of the display area DA. In an embodiment of the present invention, the component area CA may be disposed at an upper left of the display area DA. In an embodiment of the present invention, the component area CA may be disposed at an upper right of the display area DA.

In an embodiment of the present invention, the component area CA may have a shape of a circle in the plan view. However, the present invention is not limited thereto, and in an embodiment of the present invention, the component area CA may have a shape different from a shape of a circle in the plan view. For example, the component area CA may have a shape of a polygon in the plan view.

In an embodiment of the present invention, the first direction DR1 and the second direction DR2 crossing the first direction DR1 may be defined. In addition, a third direction DR3, which is perpendicular to a plane formed by the first direction DR1 and the second direction DR2, may be defined.

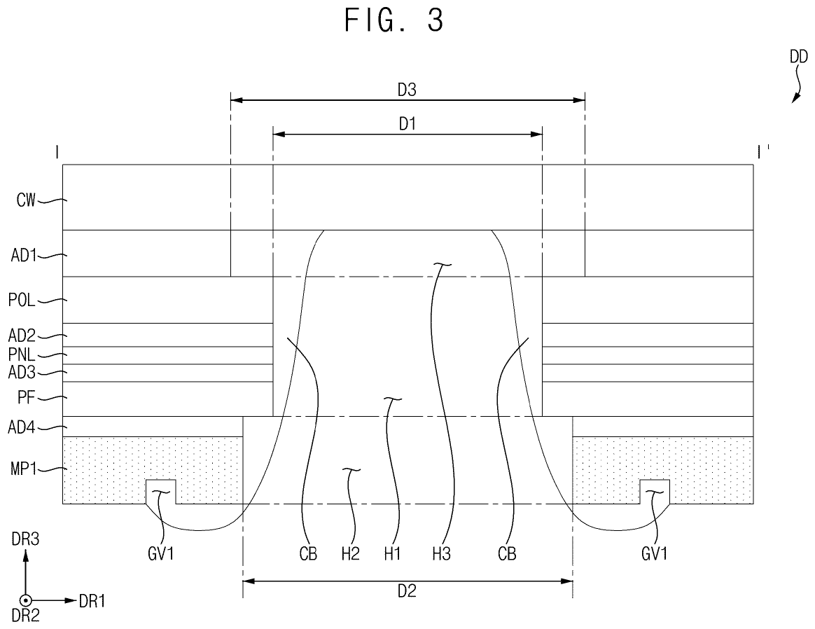

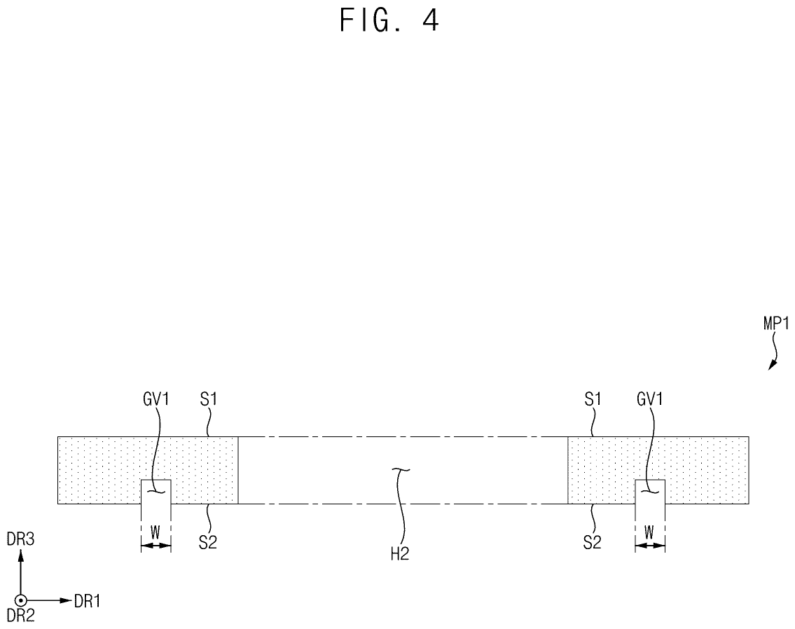

FIG. 3 is a cross-sectional view of the display device of FIG. 2 taken along line I-I′. FIG. 4 is an enlarged cross-sectional view of a metal plate included in the display device of FIG. 3. Referring to FIGS. 2 and 3, the display device DD according to an embodiment of the present invention may include a cover window CW, a first adhesive layer AD1, a polarizing plate POL, a second adhesive layer AD2, a display panel PNL, a third adhesive layer AD3, a protecting film PF, a fourth adhesive layer AD4, a metal plate MP1, and a conductive light-blocking member CB.

The cover window CW may transmit light that is emitted from the display panel PNL. For example, the cover window CW may be disposed on the polarizing plate POL. The cover window CW may protect the polarizing plate POL, the display panel PNL, and the like from external impact, heat, moisture, and the like. The cover window CW may include a material having impact resistance and light transmittance.

For example, the cover window CW may be made of glass, or may include a film made of a plastic material such as polyimide, polymethylmethacrylate (“PMMA”), polyethylene terephthalate (“PET”), or the like. These materials may be used alone or in combination with each other. However, this is only an example, and the cover window CW may include other kinds of materials.

The first adhesive layer AD1 may be disposed under the cover window CW. The first adhesive layer AD1 may be disposed under the cover window CW to provide adhesive force to the cover window CW. The first adhesive layer AD1 may define a third hole H3. For example, the third hole H3 may be defined through the first adhesive layer AD1. For example, the third hole H3 may be provided in the first adhesive layer AD1. For example, the third hole H3 may have a circular shape in the plan view; however, the present invention is not limited thereto. The third hole H3 may overlap the component area CA in the plan view.

For example, the first adhesive layer AD1 may include an optical clear adhesive (“OCA”), an optical clear resin (“OCR”), a pressure sensitive adhesive (“PSA”), or the like. These materials may be used alone or in combination with each other.

The polarizing plate POL may be disposed under the first adhesive layer AD1. The polarizing plate POL may selectively transmit light to reduce reflection of external light that is incident on the display panel PNL. For example, the display panel PNL may include metallic materials in transistors, wirings, and the like. Accordingly, external light that is incident on the display panel PNL may be reflected from the metallic material, and thus, visibility of the display device DD may be reduced. Accordingly, the polarizing plate POL may be disposed on one surface of the display panel PNL to prevent reflection of external light.

The second adhesive layer AD2 may be disposed under the polarizing plate POL. The second adhesive layer AD2 may provide adhesive force to the polarizing plate POL.

For example, the second adhesive layer AD2 may include an optical clear adhesive (“OCA”), an optical clear resin (“OCR”), a pressure sensitive adhesive (“PSA”), or the like. These materials may be used alone or in combination with each other.

The display panel PNL may be disposed under the second adhesive layer AD2. The display panel PNL may include the plurality of pixels PX. Each of the plurality of pixels PX may emit light, and accordingly, the display panel PNL may display an image through the plurality of pixels PX.

The third adhesive layer AD3 may be disposed under the display panel PNL. The third adhesive layer AD3 may provide adhesive force to the display panel PNL.

For example, the third adhesive layer AD3 may include an optical clear adhesive (“OCA”), an optical clear resin (“OCR”), a pressure sensitive adhesive (“PSA”), or the like. These materials may be used alone or in combination with each other.

The protecting film PF may be disposed under the third adhesive layer AD3. The protecting film PF may protect a lower surface of the display panel PNL. For example, the protecting film PF may include polyimide, polyethylene terephthalate, polyethylene naphthalate (“PEN”), or the like. These materials may be used alone or in combination with each other.

In an embodiment of the present invention, the polarizing plate POL, the second adhesive layer AD2, the display panel PNL, the third adhesive layer AD3, and the protecting film PF may define a first hole H1. For example, the first hole H1 may be defined through the polarizing plate POL, the second adhesive layer AD2, the display panel PNL, the third adhesive layer AD3, and the protecting film PF. For example, the first hole H1 may penetrate through the polarizing plate POL, the second adhesive layer AD2, the display panel PNL, the third adhesive layer AD3, and the protecting film PF. For example, the first hole H1 may have a shape of a circle in the plan view; however, the present invention is not limited thereto. The first hole H1 may overlap the component area CA in the plan view. For example, the first hole H1 may overlap the third hole H3 in the plan view.

The fourth adhesive layer AD4 may be disposed under the protecting film PF. The fourth adhesive layer AD4 may provide an adhesive force to the protecting film PF.

For example, the fourth adhesive layer AD4 may include an optical clear adhesive (“OCA”), an optical clear resin (“OCR”), a pressure sensitive adhesive (“PSA”), or the like. These materials may be used alone or in combination with each other.

The metal plate MP1 may be disposed under the fourth adhesive layer AD4. For example, the metal plate MP1 may be made of a rigid material to protect the display panel PNL, and the like from external impact. In addition, the metal plate MP1 may function as a heat dissipating member that emits heat generated from the display panel PNL, and the like. In addition, the metal plate MP1 may discharge static electricity generated in the cover window CW to an outside of the display device DD together with the conductive light-blocking member CB to be described later.

For example, the metal plate MP1 may include copper, graphite, or the like. These materials may be used alone or in combination with each other. However, the present invention is not limited thereto, and the metal plate MP1 may include other types of materials.

The fourth adhesive layer AD4 and the metal plate MP1 may define a second hole H2. For example, the second hole H2 may be defined through the fourth adhesive layer AD4 and the metal plate MP1. For example, the second hole H2 may be provided in the fourth adhesive layer AD4 and the metal plate MP1. For example, the second hole H2 may have a shape of a circle in the plan view; however, the present invention is not limited thereto. The second hole H2 may overlap the component area CA in the plan view. For example, the second hole H2 may overlap the first hole H1 in the plan view.

In an embodiment of the present invention, a width D2 of the second hole H2 may be greater than a width D1 of the first hole H1. In addition, a width D3 of the third hole H3 may be greater than the width D2 of the second hole H2.

However, the present invention is not limited thereto, and in an embodiment of the present invention, the width D1 of the first hole H1, the width D2 of the second hole H2, and the width D3 of the third hole H3 may be the same as each other.

In an embodiment of the present invention, the width D1 of the first hole H1 and the width D2 of the second Hole H2 may be the same as each other, and the width D1 of the first hole H1 may be less than the width D3 of the third hole H3. For example, relative sizes of the width D1 of the first hole H1, the width D2 of the second hole H2, and the width D3 of the third hole H3 may be variously changed according to embodiments of the present invention.

The conductive light-blocking member CB may be disposed in a portion of the component area CA. For example, the conductive light-blocking member CB may be disposed in the first hole H1, the second hole H2, and the third hole H3. For example, the conductive light-blocking member CB may cover a side surface of the first adhesive layer AD1 that is exposed by the third hole H3. In addition, the conductive light-blocking member CB may cover a side surface of each of the polarizing plate POL, the second adhesive layer AD2, the display panel PNL, the third adhesive layer AD3, and the protecting film PF that are exposed by the first hole H1. In addition, the conductive light-blocking member CB may cover a side surface of each of the fourth adhesive layer AD4 and the metal plate MP1 that are exposed by the second hole H2. In addition, the conductive light-blocking member CB may cover at least a portion of a lower surface of the cover window CW. In addition, the conductive light-blocking member CB may cover at least a portion of a second surface (e.g., a second surface S2 of FIG. 4) of the metal plate MP1.

The conductive light-blocking member CB may block an inflow of light that is emitted from the display panel PNL into the first hole H1, the second hole H2, and the third hole H3. In addition, static electricity may be generated in the cover window CW due to friction, and the conductive light-blocking member CB may discharge the static electricity.

The conductive light-blocking member CB may be formed through, for example, a pneumatic spray coating process, an electrostatic spray coating process, and the like. However, the present invention is not limited thereto, and the conductive light-blocking member CB may be formed in various ways.

The conductive light-blocking member CB may include a conductive ink, a conductive paste, or the like. For example, the conductive light-blocking member CB may include conductive particles such as carbon black, a conductive polymer such as PEDOT: PSS (“poly(3,4-ethylenedioxythiophene”), a conductive paste such as silver, or the like. These materials may be used alone or in combination with each other.

In an embodiment of the present invention, the conductive light-blocking member CB may cover the side surface of each of the first adhesive layer AD1, the polarizing plate POL, the second adhesive layer AD2, the display panel PNL, the third adhesive layer AD3, the protecting film PF, the fourth adhesive layer AD4, and the metal plate MP1 with a curved shape in a cross-sectional view. For example, in an embodiment of the present invention, the conductive light-blocking member CB may include an opening in the first hole H1, the second hole H2, and the third hole H3.

However, the present invention is not limited thereto, and in an embodiment of the present invention, the conductive light-blocking member CB may cover the side surface of each of the first adhesive layer AD1, the polarizing plate POL, the second adhesive layer AD2, the display panel PNL, the third adhesive layer AD3, the protecting film PF, the fourth adhesive layer AD4, and the metal plate MP1 in a straight line in the cross-sectional view.

Referring to FIGS. 2, 3, and 4, the metal plate MP1 may include a first surface S1 and a second surface S2. The first surface S1 of the metal plate MP1 may face the display panel PNL. The second surface S2 of the metal plate MP1 may be opposite to the first surface S1.

The metal plate MP1 may define a first groove GV1. For example, the first groove GV1 may be formed in the second surface S2 of the metal plate MP1. The first groove GV1 may be a portion in which at least a portion of the metal plate MP1 is removed from the second surface S2 of the metal plate MP1.

The first groove GV1 may be disposed in a portion of the display area DA. For example, the first groove GV1 may be spaced apart from the component area CA in the plan view. For example, the first groove GV1 may be spaced apart from each of the first hole H1, the second hole H2, and the third hole H3 in the plan view.

In an embodiment of the present invention, the first groove GV1 might not overlap the plurality of pixels PX in the plan view. For example, the first groove GV1 may be disposed between an area where the plurality of pixels PX are disposed and where the component area CA is provided, in the plan view. For example, the first groove GV1 may surround the component area CA.

However, the present invention is not limited thereto, and in an embodiment of the present invention, the first groove GV1 may at least partially overlap some of the plurality of pixels PX in the plan view. For example, position of the first groove GV1 may be changed within the display area DA.

The first groove GV1 may surround the component area CA in the plan view. For example, the first groove GV1 may surround the first hole H1, the second hole H2, and the third hole H3 in the plan view.

In an embodiment of the present invention, the first groove GV1 may extend along a circle in the plane view. As mentioned above, the component area CA may have a circular shape. For example, the first groove GV1 may extend along a circle having the same center as the component area CA. For example, the first groove GV1 may have an annular shape.

In an embodiment of the present invention, a width W of the first groove GV1 may be substantially constant throughout the display area DA. However, the present invention is not limited thereto, and in an embodiment of the present invention, the width W of the first groove GV1 might not be constant throughout the display area DA and may be changed in a specific area of the display area DA.

The first groove GV1 may be formed on the second surface S2 of the metal plate MP1 by using laser light. For example, the first groove GV1 may be formed on the second surface S2 of the metal plate MP1 by using a CO2 laser, an ultraviolet laser, a green laser, or the like. However, the present invention is not limited thereto, and the first groove GV1 may be formed in various ways.

As mentioned above, the conductive light-blocking member CB may cover a portion of the second surface S2 of the metal plate MP1. In this case, a phenomenon, in which the conductive light-blocking member CB deviates from a designed area on the second surface S2 of the metal plate MP1 and excessively spreads, may occur.

The metal plate MP1 according to an embodiment of the present invention may include the first groove GV1. Accordingly, the conductive light-blocking member CB may be prevented from spreading excessively outside the designed area on the second surface S2 of the metal plate MP1. For example, the conductive light-blocking member CB may fill the first groove GV1, and thus, an excessive spread of the conductive light-blocking member CB on the second surface S2 of the metal plate MP1 may be prevented. For example, the first groove GV1 serves as a kind of dam, and thus, the conductive light-blocking member CB may be prevented from being excessively applied to the second surface S2 of the metal plate MP1.

FIG. 5 is a cross-sectional view illustrating a pixel that is included in the display device of FIG. 2.

Referring to FIG. 5, each of the plurality of pixels PX may include a substrate SUB, a buffer layer BUF, a gate insulating layer GI, an interlayer insulating layer ILD, a via insulating layer VIA, an active layer ACT, a source electrode SE, a gate electrode GE, a drain electrode DE, a pixel electrode PE, a pixel defining layer PDL, a light emitting layer EML, a common electrode CE, and an encapsulating layer TFE.

The substrate SUB may include a transparent material or an opaque material. The substrate SUB may be formed of a transparent resin substrate. Example of the transparent resin substrate may include a polyimide substrate. In this case, for example, the polyimide substrate may include a first organic layer, a first barrier layer, a second organic layer, and the like.

In addition, the substrate SUB may include, for example, a quartz substrate (e.g. a synthetic quartz substrate, a fluorine-doped quartz substrate), a calcium fluoride substrate, a sodalime glass substrate, a non-alkali glass substrate, or the like. These materials may be used alone or in combination with each other.

The buffer layer BUF may be disposed on the substrate SUB. The buffer layer BUF may prevent metal atoms or impurities from diffusing from the substrate SUB to the transistor TR. In addition, the buffer layer BUF can increase the flatness of a surface of the substrate SUB when the surface of the substrate SUB is not uniform.

For example, the buffer layer BUF may include an inorganic material such as silicon oxide, silicon nitride, silicon oxynitride, or the like. These materials may be used alone or in combination with each other.

The active layer ACT may be disposed on the buffer layer BUF. The active layer ACT may include, for example, an inorganic semiconductor (e.g., amorphous silicon, polysilicon, a metal oxide semiconductor), an organic semiconductor, or the like. These materials may be used alone or in combination with each other. The active layer ACT may include a source area, a drain area, and a channel area that is disposed between the source area and the drain area.

For example, the metal oxide semiconductor may include a binary compound (“ABₓ”), a ternary compound (“ABₓC_{y}”), a quaternary compound (“ABₓC_{y}D_{z}”), or the like including indium (“In”), zinc (“Zn”), gallium (“Ga”), tin (“Sn”), titanium (“Ti”), aluminum (“Al”), hafnium (“Hf”), zirconium (“Zr”), magnesium (“Mg”), or the like. These materials may be used alone or in combination with each other.

For example, the metal oxide semiconductor may include zinc oxide (“ZnOₓ”), gallium oxide (“GaOₓ”), tin oxide (“SnOₓ”), indium oxide (“InOₓ”), indium gallium oxide (“IGO”), indium zinc oxide (“IZO”), indium tin oxide (“ITO”), indium zinc tin oxide (“IZTO”), and indium gallium zinc oxide (“IGZO”). These materials may be used alone or in combination with each other.

The gate insulating layer GI may be disposed on the buffer layer BUF. The gate insulating layer GI may cover the active layer ACT. For example, the gate insulating layer GI may cover the active layer ACT and may be disposed along a profile of the active layer ACT.

For example, the gate insulating layer GI may include inorganic materials such as silicon oxide (“SiOₓ”), silicon nitride (“SiNₓ”), silicon carbide (“SiCₓ”), silicon oxynitride (“SiOₓN_{y}”), silicon oxycarbide (“SiOₓC_{y}”), or the like. These materials may be used alone or in combination with each other.

The gate electrode GE may be disposed on the gate insulating layer GI. The gate electrode GE may overlap the channel area of the active layer ACT in the plan view.

For example, the gate electrode GE may include a metal, an alloy, a metal nitride, a conductive metal oxide, a transparent conductive material, or the like. Examples of the metal may include silver (“Ag”), molybdenum (“Mo”), aluminum (“Al”), tungsten (“W”), copper (“Cu”), nickel (“Ni”), chromium (“Cr”), titanium (“Ti”), tantalum (“Ta”), platinum (“Pt”), scandium (“Sc”), or the like. These materials may be used alone or in combination with each other.

Examples of the conductive metal oxide may include Indium tin oxide, indium zinc oxide, or the like. In addition, examples of the metal nitride may include aluminum nitride (“AlN«”), tungsten nitride (“WNₓ”), chromium nitride (“CrNₓ”), or the like. These materials may be used alone or in combination with each other.

The interlayer insulating layer ILD may be disposed on the gate insulating layer GI. The interlayer insulating layer ILD may cover the gate electrode GE. For example, the interlayer insulating layer ILD may cover the gate electrode GE, and may be disposed along a profile of the gate electrode GE.

For example, the interlayer insulating layer ILD may include inorganic materials such as silicon oxide, silicon nitride, silicon carbide, silicon oxynitride, silicon oxycarbide, or the like. These materials may be used alone or in combination with each other.

The source electrode SE may be disposed on the interlayer insulating layer ILD. The source electrode SE may be connected to the source area of the active layer ACT through a contact hole that penetrates the gate insulating layer GI and the interlayer insulating layer ILD.

The drain electrode DE may be disposed on the interlayer insulating layer ILD. The drain electrode DE may be connected to the drain area of the active layer ACT through a contact hole that penetrates the gate insulating layer GI and the interlayer insulating layer ILD.

For example, the source electrode SE may include a metal, an alloy, a metal nitride, a conductive metal oxide, a transparent conductive material, or the like. These materials may be used alone or in combination with each other. The drain electrode DE and the source electrode SE may be formed through the same process as each other and may include the same material.

The transistor TR may include the active layer ACT, the source electrode SE, the gate electrode GE, and the drain electrode DE.

The via insulating layer VIA may be disposed on the interlayer insulating layer ILD. The via insulating layer VIA may cover the source electrode SE and the drain electrode DE. The via insulating layer VIA may include an organic material. For example, the via insulating layer VIA may include organic materials such as phenolic resin, acrylic resin, polyimide resin, polyamide resin, siloxane resin, epoxy resin, or the like. These materials may be used alone or in combination with each other.

The pixel electrode PE may be disposed on the via insulating layer VIA. The pixel electrode PE may be connected to the drain electrode DE through a contact hole that penetrates the via insulating layer VIA.

The pixel electrode PE may include, for example, a metal, an alloy, a metal nitride, a conductive metal oxide, a transparent conductive material, or the like. These materials be used alone or in combination with each other. In an embodiment of the present invention, the pixel electrode PE may have a stacked structure including ITO/Ag/ITO. For example, the pixel electrode PE may operate as an anode.

The pixel defining layer PDL may be disposed on the via insulating layer VIA. The pixel defining layer PDL may cover side portions of the pixel electrode PE. In addition, an opening exposing a portion of the upper surface of the pixel electrode PE may be formed in the pixel defining layer PDL.

For example, the pixel defining layer PDL may include an inorganic material or an organic material. In an embodiment of the present invention, the pixel defining layer PDL may include an organic material such as an epoxy resin, a siloxane resin, or the like. These materials may be used alone or in combination with each other. In an embodiment of the present invention, the pixel defining layer PDL may further include a light-blocking material including a black pigment, a black dye, or the like.

The light emitting layer EML may be disposed on the pixel electrode PE. The light emitting layer EML may include an organic material that emits light of a predetermined color. For example, the light emitting layer EML may include an organic material that emits red light. However, the present invention is not limited thereto, and the light emitting layer EML may emit light of a color that is different from red light.

The common electrode CE may be disposed on the light emitting layer EML and the pixel defining layer PDL. The common electrode CE may include, for example, a metal, an alloy, a metal nitride, a conductive metal oxide, a transparent conductive material, or the like. These materials may be used alone or in combination with each other. The common electrode CE may operate as a cathode.

A light emitting element LED may include the pixel electrode PE, the light emitting layer EML, and the common electrode CE.

The encapsulation layer TFE may be disposed on the common electrode CE. The encapsulation layer TFE may prevent impurities and moisture from penetrating into the pixel electrode PE, the light emitting layer EML, and the common electrode CE from the outside. The encapsulation layer TFE may include at least one inorganic layer and at least one organic layer.

For example, the inorganic layer may include silicon oxide, silicon nitride, silicon oxynitride, or the like. These materials may be used alone or in combination with each other. For example, the organic layer may include a polymer cured product such as polyacrylate.

Although an embodiment of each of the plurality of pixels PX has been described with reference to FIG. 5, each of the plurality of pixels PX is not limited to the structure illustrated in FIG. 5. For example, each of the plurality of pixels PX may include all structures that receive an electrical signal and emit light having a luminance corresponding to the intensity of the electrical signal.

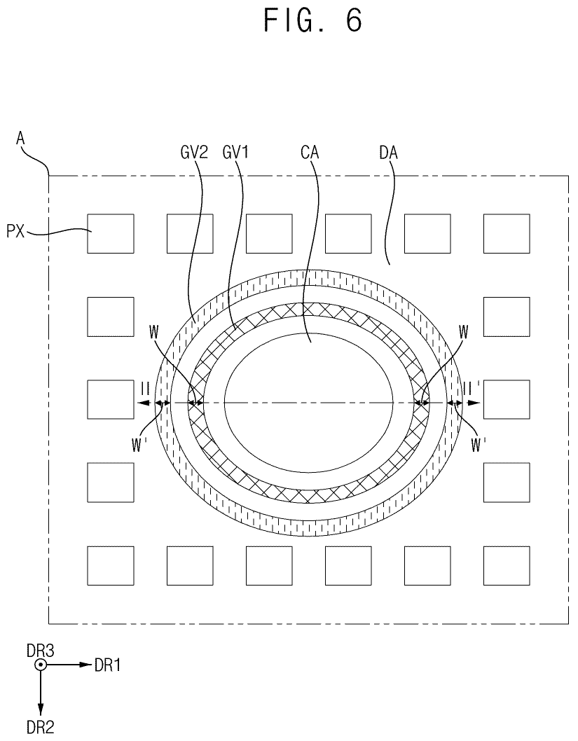

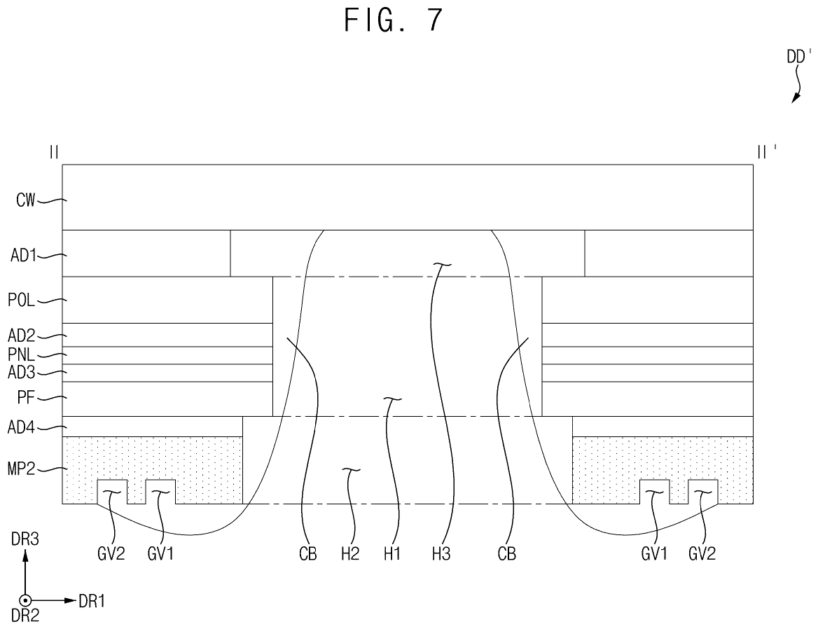

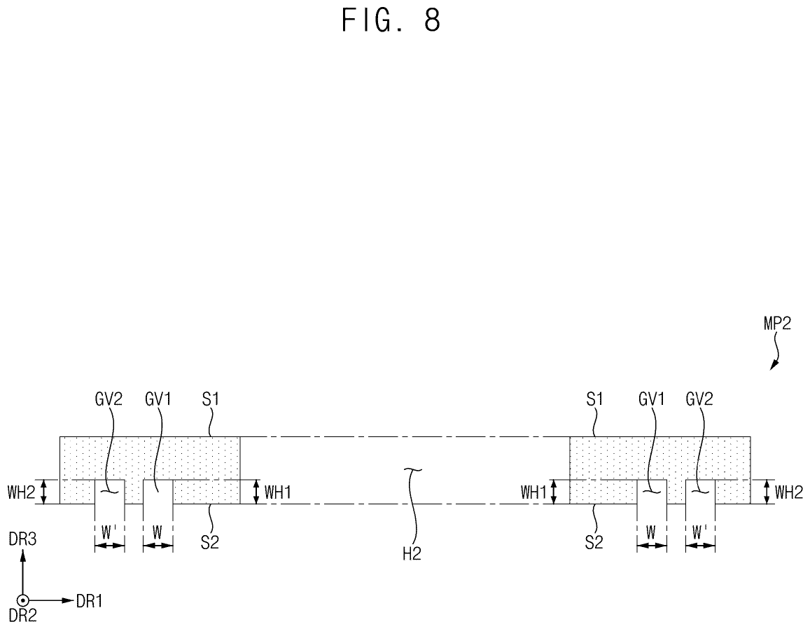

FIG. 6 is a plan view illustrating an example of area A of FIG. 1. FIG. 7 is a cross-sectional view illustrating an example of the display device of FIG. 6 taken along line II-II′. FIG. 8 is an enlarged cross-sectional view of a metal plate included in the display device of FIG. 7.

A display device DD′ described with reference to FIGS. 6, 7 and 8 may be substantially the same as or similar to the display device DD described with reference to FIGS. 2, 3 and 4 except for a configuration of the metal plate MP2. Thus, overlapping descriptions may be omitted or simplified.

Referring to FIGS. 6, 7, and 8, a display device DD′ according to an embodiment of the present invention may include the cover window CW, the first adhesive layer AD1, the polarizing plate POL, the second adhesive layer AD2, the display panel PNL, the third adhesive layer AD3, the protecting film PF, the fourth adhesive layer AD4, a metal plate MP2, and the conductive light-blocking member CB.

The metal plate MP2 may define a second groove GV2. For example, the second groove GV2 may be formed in the second surface S2 of the metal plate MP2. The second groove GV2 may be a portion in which at least a portion of the metal plate MP2 is removed from the second surface S2 of the metal plate MP2.

The second groove GV2 may be disposed in a portion of the metal plate MP2 that is in the display area DA. The second groove GV2 may be spaced apart from the first groove GV1 in the plan view. For example, the second groove GV2 may surround the first groove GV1 in the plan view. In an embodiment of the present invention, the second groove GV2 may extend along a circle having the same center as the first groove GV1. For example, the first groove GV1 may extend along a first circle in the plan view. The second groove GV2 may extend along a second circle in the plan view, and the first circle and the second circle may have substantially the same center. For example, the second groove GV2 may have an annular shape that surrounds the first groove GV1. For example, the first groove GV1 and the second groove GV2 may have the same center as the component area CA.

In an embodiment of the present invention, the second groove GV2 might not overlap the plurality of pixels PX in the plan view. For example, the second groove GV2 may be disposed between an area where the first groove GV1 is disposed and an area where the plurality of pixels PX are disposed in the plan view.

However, the present invention is not limited thereto, and in an embodiment of the present invention, the second groove GV2 may at least partially overlap some of the plurality of pixels PX in the plan view. For example, a position of the second groove GV2 may be changed within the display area DA.

In an embodiment of the present invention, a width W′ of the second groove GV2 may be constant throughout the display area DA. However, the present invention is not limited thereto, and in an embodiment of the present invention, the width W′ of the second groove GV2 might not be constant throughout the display area DA and may be changed in a specific area of the display area DA.

In an embodiment of the present invention, the width W′ of the second groove GV2 and the width W of the first groove GV1 may be substantially the same as each other. However, the present invention is not limited thereto, and in an embodiment of the present invention, the width W′ of the second groove GV2 may be greater than the width W of the first groove GV1. In an embodiment of the present invention, the width W′ of the second groove GV2 may be less than the width W of the first groove GV1.

In an embodiment of the present invention, a height WH2 of the second groove GV2 in the third direction DR3 and a height WH1 of the first groove GV1 in the third direction DR1 may be substantially the same as each other. However, the present invention is not limited thereto, and in an embodiment invention, the height WH2 of the second groove GV2 in the third direction DR3 may be greater than the height WH1 of the first groove GV1 in the third direction DR3. In an embodiment of the present invention, the height WH2 of the second groove GV2 in the third direction DR3 may be less than the height WH1 of the first groove GV1 in the third direction DR3.

The second groove GV2 may be formed on the second surface S2 of the metal plate MP2 by using laser light. For example, the second groove GV2 may be formed on the second surface S2 of the metal plate MP2 by using a CO2 laser, an ultraviolet laser, a green laser, or the like. However, the present invention is not limited thereto, and the second groove GV2 may be formed in various ways.

As the metal plate MP2 includes the first groove GV1 and the second groove GV2 provided therein, the conductive light-blocking member CB may be prevented from spreading excessively outside the designed area on the second surface S2 of the metal plate MP1. For example, the conductive light-blocking member CB may fill the first groove GV1. In addition, the conductive light-blocking member CB may fill at least a portion of the second groove GV2. Accordingly, an excessive spread of the conductive light-blocking member CB on the second surface S2 of the metal plate MP1 may be prevented.

FIGS. 6, 7, and 8 may illustrate examples in which two grooves are provided in the second surface S2 of the metal plate MP2. However, the present invention is not limited thereto, and three or more grooves may be provided in the second surface S2 of the metal plate MP2. As the number of grooves provided in the second surface S2 of the metal plate MP2 increases, the probability that the conductive light-blocking member CB excessively spreads on the second surface S2 of the metal plate MP2 may be further reduced.

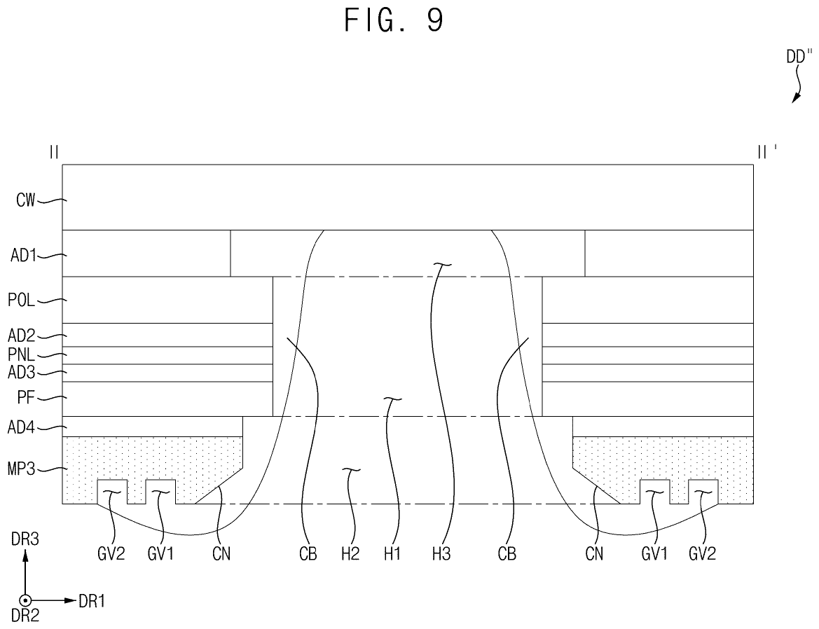

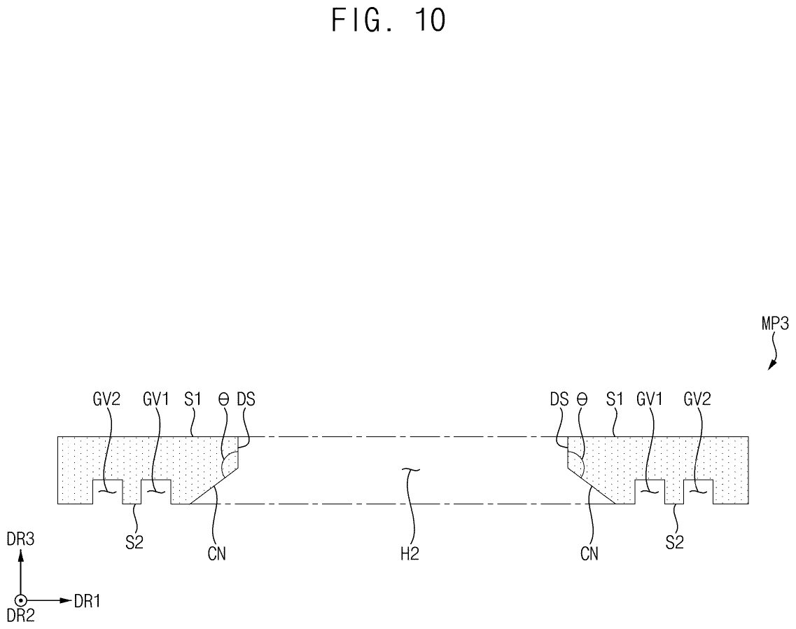

FIG. 9 is a cross-sectional view illustrating an example of the display device of FIG. 6 taken along line II-II′. FIG. 10 is an enlarged cross-sectional view of a metal plate included in the display device of FIG. 9.

A display device DD″ described with reference to FIGS. 9 and 10 may be substantially the same as or similar to the display device DD′ described with reference to FIGS. 7 and 8, except for a configuration of the metal plate MP3. Thus, overlapping descriptions may be omitted or simplified.

Referring to FIGS. 9 and 10, a display device DD″ according to an embodiment of the present invention may include the cover window CW, the first adhesive layer AD1, the polarizing plate POL, the second adhesive layer AD2, the display panel PNL, the third adhesive layer AD3, the protecting film PF, the fourth adhesive layer AD4, a metal plate MP3, and the conductive light-blocking member CB.

The metal plate MP3 may include a first surface S1, a second surface S2, a side surface DS and an edge CN. The first surface S1 of the metal plate MP3 may face the display panel PNL. The second surface S2 of the metal plate MP3 may be opposite to the first surface S1.

The side surface DS of the metal plate MP3 may connect the first surface S1 and the second surface S2. For example, the side surface DS of the metal plate MP3 may be a surface exposed through the second hole H2. For example, the side surface DS may be an inner surface that defines the second hole H2.

The edge CN of the metal plate MP3 may be spaced apart from the first surface S1 in the cross-sectional view. For example, the edge CN of the metal plate MP3 may be spaced apart from the first surface S1 in a direction that is opposite to the third direction DR3.

In an embodiment of the present invention, the edge CN of the metal plate MP3 may have a chamfered shape in the cross-sectional view. For example, the edge CN of the metal plate MP3 may have a shape that approaches a center of the second hole H2 as the edge CN approaches the display panel PNL. For example, the edge CN of the metal plate MP3 may have a shape that is farther away from the center of the second hole H2 as the edge CN of the metal plate MP3 extends away from the display panel PNL. The center of the second hole H2 may substantially coincide with the center of a component area (e.g., the component area CA of FIG. 6) having a shape of a circle the plan view. For example, the edge CN of the MP3 may have an inward slanted shape.

In an embodiment of the present invention, an angle θ between the edge CN and the side surface DS of the metal plate MP3 may be an obtuse angle. However, the present invention is not limited thereto, and in an embodiment, the angle θ between the edge CN and the side surface DS of the metal plate MP3 may be a substantially right angle. In an embodiment of the present invention, the angle θ between the edge CN and the side surface DS of the metal plate MP3 may be an acute angle.

When the conductive light-blocking member CB is applied only to an area that is smaller than the designed area on the second surface S2 of the metal plate MP3, the metal plate MP3 and the conductive light-blocking member CB may be easily separated from each other by an external impact or force.

As the edge CN of the metal plate MP3 has the chamfered shape, the conductive light-blocking member CB may be applied to the designed area on the second surface S2 of the metal plate MP3. Accordingly, the metal plate MP3 and the conductive light-blocking member CB might not be easily separated from each other by an external impact or force.

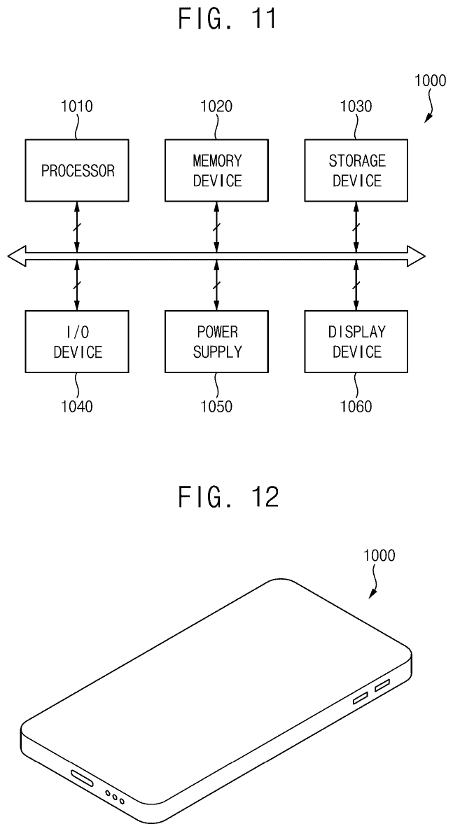

FIG. 11 is a block diagram illustrating an electronic device according to embodiments. FIG. 12 is a diagram illustrating an example in which the electronic device of FIG. 11 is implemented as a smart phone.

Referring to FIGS. 11 and 12, an electronic device 1000 may include a processor 1010, a memory device 1020, a storage device 1030, an input/output device 1040, a power supply 1050, and a display device 1060. In this case, the display device 1060 may be the display device DD of FIG. 1. In addition, the electronic device 1000 may further include several ports capable of communicating with a video card, a sound card, a memory card, a USB device, and/or the like. According to an embodiment, as illustrated in the FIG. 12, the electronic device 1000 may be implemented as a smartphone. However, this is exemplary, and the electronic device 1000 may be implemented as various devices according to embodiments. For example, the electronic device 1000 may be implemented as a mobile phone, a video phone, a smart pad, a smart watch, a tablet PC, a vehicle navigation device, a computer monitor, a notebook computer, a head mounted display device, and/or the like.

The processor 1010 may be a microprocessor, a central processing unit, an application processor, and/or the like. The processor 1010 may be connected to other components through an address bus, a control bus, a data bus, and/or the like. In an embodiment, the processor 1010 may also be connected to an expansion bus such as a peripheral component interconnect (“PCI”) bus.

The memory device 1020 may store data necessary for operation of the electronic device 1000. For example, the memory device 1020 may include a nonvolatile memory device and/or a volatile memory device. Examples of the nonvolatile memory device may include erasable programmable read-only Memory (“EPROM”) device, electrically erasable programmable read-only memory (“EEPROM”) device, flash memory device, phase change random access memory (“PRAM”) device, resistance random access memory (“RRAM”) device, nano floating gate memory (“NFGM”) device, polymer random access memory (“PoRAM”) device, magnetic random access memory (“MRAM”) device, ferroelectric random access memory (“FRAM”) device, and/or the like. Example of the volatile memory device may include dynamic random access memory (“DRAM”) device, static random access memory (“SRAM”) device, mobile DRAM device, and/or the like.

The storage device 1030 may include a solid state drive (“SSD”), a hard disk drive (“HDD”), a CD-ROM, and/or the like.

The input/output device 1040 may include an input mean such as a keyboard, a keypad, a touch pad, a touch screen, and a mouse, and/or the like, and an output mean such as a speaker and a printer. In an embodiment, the display device 1060 may be included in the input/output device 1040.

The power supply 1050 may supply power necessary for operation of the electronic device 1000. For example, the power supply 1050 may supply power necessary for operation of the display device 1060.

The display device 1060 may be connected to other components through buses or other communication links.

The present invention can be applied to various display devices. For example, the present invention is applicable to various display devices such as display devices for vehicles, ships and aircraft, portable communication devices, display devices for exhibition or information transmission, medical display devices, and the like.

While the present invention has been described with reference to embodiments thereof, it will be understood by those of ordinary skill in the art that various changes in form and details may be made thereto without departing from the spirit and scope of the present invention.

What is claimed is:

1. A display device comprising:
a display panel including a display area, in which a plurality of pixels are arranged, and a component area that is adjacent to the display area, wherein a first hole is provided in the display panel and overlaps the component area; and
a metal plate disposed under the display panel, wherein a second hole is provided in the metal plate and overlaps the first hole, and wherein a first groove is provided in the metal plate and is spaced apart from the second hole.

2. The display device of claim 1, wherein the metal plate includes a first surface, which faces the display panel, and a second surface opposite to the first surface, and the first groove is provided in the second surface.

3. The display device of claim 2, wherein the first groove is a portion in which a portion of the metal plate is removed from the second surface of the metal plate.

4. The display device of claim 3, wherein the first groove is disposed in a portion of the display area.

5. The display device of claim 1, wherein the first groove surrounds the second hole.

6. The display device of claim 5, wherein the first groove has an annular shape.

7. The display device of claim 1, wherein a second groove is provided in the metal plate and is spaced apart from the first groove.

8. The display device of claim 7, wherein the metal plate includes a first surface, which faces the display panel, and a second surface opposite to the first surface, and each of the first groove and the second groove is provided in the second surface.

9. The display device of claim 8, wherein each of the first groove and the second groove is a portion in which a portion of the metal plate is removed from the second surface of the metal plate.

10. The display device of claim 9, wherein a height of the first groove and a height of the second groove are a same as each other.

11. The display device of claim 7, wherein the second groove surrounds the first groove.

12. The display device of claim 11, wherein the first groove extends along a first circle, and the second groove extends along a second circle.

13. The display device of claim 1, wherein an edge of the metal plate has a chamfered shape in a cross-sectional view.

14. The display device of claim 13, wherein the metal plate includes a first surface, which faces the display panel, and a second surface opposite to the first surface, and the edge of the metal plate is spaced apart from the first surface, in the cross-sectional view.

15. The display device of claim 14, wherein the edge of the metal plate has a shape that approaches a center of the second hole as the edge approaches the display panel.

16. The display device of claim 14, wherein the metal plate includes a side surface connecting the first surface and the second surface to each other, wherein an angle between the chamfered edge of the metal plate and the side surface of the metal plate is an obtuse angle.

17. The display device of claim 1, further comprising:
conductive light-blocking member covering a side surface of the display panel that is exposed through the first hole.

18. The display device of claim 17, wherein the conductive light-blocking member covers a side surface of the metal plate that is exposed through the second hole.

19. The display device of claim 18, wherein the conductive light-blocking member fills at least a portion of the first groove.

20. The display device of claim 19, wherein the metal plate includes a second groove that is spaced apart from the first groove, and the conductive light-blocking member fills the first groove and at least a portion of the second groove.

21. A display device comprising:
a display panel including a display area, in which a plurality of pixels are arranged, and an auxiliary area that is adjacent to the display area, wherein the display panel includes a first hole overlapping the auxiliary area; and
a metal plate disposed on the display panel, wherein the metal plate includes a second hole and a first groove, wherein the second hole overlaps the first hole, and the first groove is spaced apart from the second hole.

22. The display device of claim 21, wherein the auxiliary area is disposed between adjacent pixels among the plurality of pixels.

23. The display device of claim 21, wherein the metal plate includes a first surface, which faces the display panel, and a second surface opposite to the first surface, and wherein the first groove is provided in the second surface.

24. The display device of claim 23, wherein the first groove is a portion in which a portion of the metal plate is removed from the second surface of the metal plate.

25. The display device of claim 24, wherein the first groove is disposed in a portion of the display area.

26. The display device of claim 21, wherein the first groove surrounds the second hole.

27. The display device of claim 26, wherein the first groove extends along a circle.

28. An electronic device comprising:
a display panel including a display area, in which a plurality of pixels are arranged, and a component area that is adjacent to the display area, wherein a first hole is provided in the display panel and overlaps the component area;
a metal plate disposed under the display panel, wherein a second hole is provided in the metal plate and overlaps the first hole, and wherein a first groove is provided in the metal plate and is spaced apart from the second hole; and
a memory device configured to store data.
